(19) United States
(12) Patent Application Publication
(10) Pub. No.: US 2008/0200017 A1
(43) Pub. Date: Aug. 21, 2008

(54) Method of producing semiconductor device

(75) Inventor: Yasuhiro Doumae, Tokyo (JP)

Correspondence Address: TAKUCHI & KUBOTERA, LLP, Suite 202, 200 Daingerfield Road, Alexandria, VA, 22314, US

(73) Assignee: Oki Electric Industry Co., Ltd

(21) Appl. No.: 12/003,287

(22) Filed: Dec. 21, 2007

(30) Foreign Application Priority Data
Feb. 16, 2007 (JP) 2007-036721

(51) Int. Cl. H01L 21/223

(52) U.S. Cl. 438/528; 257/E21.143

(57) ABSTRACT

A method of producing a semiconductor device includes the steps of: introducing a p-type impurity corresponding to a conductive type of a channel area into a channel forming area; introducing fluorine into the channel forming area at a low acceleration voltage; and thermally processing a substrate to increase a threshold voltage. In the method of the present invention, the step of thermally processing the substrate is performed after the steps of introducing the p-type impurity into the channel forming area and introducing fluorine into the channel forming area. Further, the steps of introducing the p-type impurity into the channel forming area and introducing fluorine into the channel forming area may be performed any order.

### BACKGROUND OF THE INVENTION AND RELATED ART STATEMENT

The present invention relates to a method of producing a semiconductor device. In particular, the present invention relates to a method of producing an n-type Metal Oxide Semiconductor Field Effect Transistor (MOSFET) using a Silicon on Insulator (SOI) substrate, in which it is possible to adjust a threshold voltage without inducing a floating body effect.

In a conventional MOSFET formed in an SOI substrate (also called as an SOI-MOSFET), an element separation area is formed in an SOI layer to reach an embedded insulation layer (BOX layer), so that individual element areas defined with the element separation area are electrically separated. In this configuration, each of the individual element areas is covered with the element separation area on a side surface thereof and covered with the BOX layer on a backside surface thereof, respectively.

Accordingly, when the element separation area is formed in the SOI substrate, it is possible to securely separate the individual element areas including a channel area as opposed to a semiconductor substrate without the BOX layer. Further, in an SOI-MOSFET disclosed in Patent Reference 1, fluorine ions are introduced into a channel area for suppressing a short channel effect.

In the n-type SOI-MOSFET, in order to increase a threshold voltage, it is necessary to introduce a p-type impurity in the channel area at a high concentration. In general, when a layer thickness of a gate insulation layer disposed between the channel area and a gate electrode disposed above the channel area decreases, the threshold voltage tends to decrease. Accordingly, when a size of an element and a layer thickness of the gate insulation layer decrease, the threshold voltage tends to decrease. Accordingly, when an element with a small size is produced, it is necessary to introduce a p-type impurity at a further high concentration, thereby preventing the threshold voltage from decreasing.

In the conventional SOI-MOSFET described above, the individual element area including the channel are is covered with the element separation area on the side surface thereof and covered with the BOX layer on the backside surface thereof, respectively. Accordingly, when the p-type impurity is introduced at a high concentration, a potential of the channel area with the p-type impurity thus introduced becomes a floating state. As a result, an end portion of a drain has a high electric field, and the p-type impurity changes to impact ions at the end portion, thereby accumulating holes thus generated in the channel area. In a case of a partially depleted type SOI-MOSFET having a relatively thick SOI layer, it is difficult to discharge the holes thus generated, thereby easily causing a floating body effect such as single latchup, kink, and the likes unique to the SOI-MOSFET.

The single latchup is a phenomenon in which carriers generated at the channel area due to the impact ionization become a base current, thereby operating a parasite bipolar transistor having an emitter, a base, and a collector corresponding to a source, a channel, and a drain, respectively. The kink is a phenomenon in which, among the carriers generated at the channel area due to the impact ionization, positive holes are accumulated in the channel area to decrease the threshold voltage, thereby rapidly reducing a drain current.

In order to suppress the floating body effect, Patent Reference 2 has disclosed a semiconductor device in which an embedded impurity area is formed in a channel area. An impurity having a conductive type opposite to that in the channel area and the same as that in a source area and a drain area is introduced into the embedded impurity area. Further, the embedded impurity area is disposed to contact with a BOX layer, and is separated from the source area and the drain area.

In Patent Reference 2, the semiconductor device is produced through the following process. First, an n-type impurity is introduced into a whole element area of an SOI substrate up to a depth reaching the BOX layer. In the next step, a p-type impurity corresponding to a conductive type of a channel area is introduced into a surface portion of the element area.

In the next step, a gate insulation film and a gate electrode are sequentially formed on the element area. Then, while a gate electrode portion formed of the gate insulation film and the gate electrode is used as a mask, a p-type impurity is introduced up to a depth reaching the BOX layer one more time. Accordingly, only an n-type impurity area remains below the gate electrode portion, and other areas become a p-type impurity area. The n-type impurity area below the gate electrode portion becomes the embedded impurity area.

In the next step, sidewalls are formed on both side surfaces of the gate electrode portion. Then, while the gate electrode portion and the sidewalls are used as a mask, an n-type impurity is introduced into the element area. Accordingly, a source area and a drain area are formed in areas where the n-type impurity is introduced. At this time, the p-type impurity area below the gate electrode portion and the sidewalls remains as a channel area, where the n-type impurity is not introduced. The embedded impurity area is covered with the channel area or the p-type impurity area, and is separated from the source area and the drain area.

In the semiconductor device thus produced, the channel area is completely depleted through a contact potential between the embedded impurity area and the channel area. Accordingly, when a p-type impurity is introduced into the channel area at a high concentration for increasing a threshold voltage, it is possible to prevent the floating body effect.
Patent Reference 1: Japanese Patent Publication No. 2006-59843
Patent Reference 2: Japanese Patent Publication No. 11-087719

In the conventional semiconductor device described in Patent Reference 2, in addition to the channel area, the source area, the drain area, and the gate electrode constituting an ordinary MOSFET, it is necessary to form the embedded impurity area. As described above, the embedded impurity area is formed as the impurity area having a conductive type opposite to that of the channel area, and is disposed to contact with the BOX layer and be away from the source area and the drain area.

As described above, when the SOI-MOSFET having the embedded impurity area is produced, it is necessary to introduce the p-type impurity and the n-type impurity for several times. Accordingly, in the conventional semiconductor device described in Patent Reference 2, the number of production processes increases, thereby lowering manufacturing put-through.

In view of the problems described above, an object of the present invention is to provide a method of producing a semiconductor device to solve the problems of the conventional semiconductor device. In particular, in the method of producing a semiconductor device of the invention, it is possible to increase a threshold voltage of an n-type SOI-MOSFET without inducing the floating body effect, and produce the semiconductor with improved put-through.

Further objects and advantages of the invention will be apparent from the following description of the invention.

### SUMMARY OF THE INVENTION

In order to attain the objects described above, according to the present invention, a method of producing a semiconductor device includes the steps of: introducing a p-type impurity corresponding to a conductive type of a channel area into a channel forming area; introducing fluorine into the channel forming area at a low acceleration voltage; and thermally processing a substrate to increase a threshold voltage. In the method of the present invention, the step of thermally processing the substrate is performed after the steps of introducing the p-type impurity into the channel forming area and introducing fluorine into the channel forming area. Further, the steps of introducing the p-type impurity into the channel forming area and introducing fluorine into the channel forming area may be performed any order.

In the method of the present invention, the p-type impurity and fluorine are introduced into the channel forming area corresponding to the channel area of an MOSFET to be produced. Accordingly, it is possible to increase a threshold voltage of the MOSFET through the introduction of fluorine into the channel forming area. As a result, it is not necessary to increase a concentration of the P-type impurity in the channel area. Therefore, it is possible to make an SOI layer of the MOSFET completely depleted.

In the method of the present invention, it is possible to increase the threshold voltage without inducing the floating body effect. When fluorine is introduced into the channel forming area at a lower acceleration voltage, that is, when fluorine is introduced into the channel forming area by a smaller depth from an upper surface thereof, the threshold voltage increases. Accordingly, it is possible to prevent the floating body effect from occurring upon increasing the threshold voltage of the MOSFET.

In the method of the present invention, the step of introducing fluorine into the channel forming area at a low acceleration voltage may be added to a conventional production flow for adjusting the threshold voltage when the MOSFET is produced using the SOI substrate. Accordingly, different from a semiconductor device disclosed in Patent Reference 2, it is possible to prevent production put-through from lowering upon adjusting the threshold voltage.

### BRIEF DESCRIPTION OF THE DRAWINGS

FIGS. 1(A) to 1(C) are schematic views No. 1 showing a process of producing a semiconductor device according to a first embodiment of the present invention;

FIGS. 2(A) to 2(C) are schematic views No. 2 showing the process of producing the semiconductor device continued from FIG. 1(C) according to the first embodiment of the present invention;

FIGS. 3(A) and 3(B) are schematic views No. 3 showing the process of producing the semiconductor device continued from FIG. 2(C) according to the first embodiment of the present invention;

FIG. 4 is a graph showing a relationship between a drain current and a gate voltage of the semiconductor device for evaluating a threshold voltage of an n-type SOI-MOSFET (Silicon on Insulator-Metal Oxide Semiconductor Field Effect Transistor) according to the first embodiment of the present invention;

FIG. 5 is a graph showing a relationship between the drain current and the gate voltage of the semiconductor device for evaluating single latchup property of the n-type SOI-MOSFET according to the first embodiment of the present invention;

FIG. 6 is a graph showing a relationship between the drain current and the gate voltage of the semiconductor device for evaluating the single latchup property of the n-type SOI-MOSFET according to the first embodiment of the present invention;

FIG. 7 is a graph showing a relationship between the drain current and a drain voltage of the semiconductor device for evaluating kink property of the n-type SOI-MOSFET according to the first embodiment of the present invention; and

FIG. 8 is a graph showing a relationship between the drain current and the drain voltage of the semiconductor device for evaluating the kink property of the n-type SOI-MOSFET according to the first embodiment of the present invention.

### DETAILED DESCRIPTION OF PREFERRED EMBODIMENTS

Hereunder, embodiments of the present invention will be explained with reference to the accompanying drawings. The drawings are just illustratively showing a shape, a size, and a dimensional arrangement of a component for explaining the embodiments, and the invention is not limited to those shown in the drawings.

### First Embodiment

A first embodiment of the present invention will be explained. In the first embodiment, when an n-type SOI-MOSFET (Silicon on Insulator-Metal Oxide Semiconductor Field Effect Transistor) is produced, fluorine is introduced into a channel forming area, so that a threshold voltage of a semiconductor device thus produced is increased.

A method of producing the semiconductor device includes a p-type impurity introduction step, a fluorine introduction step, and a thermal processing step. These steps may be added to a conventional production process of producing the n-type SOI-MOSFET.

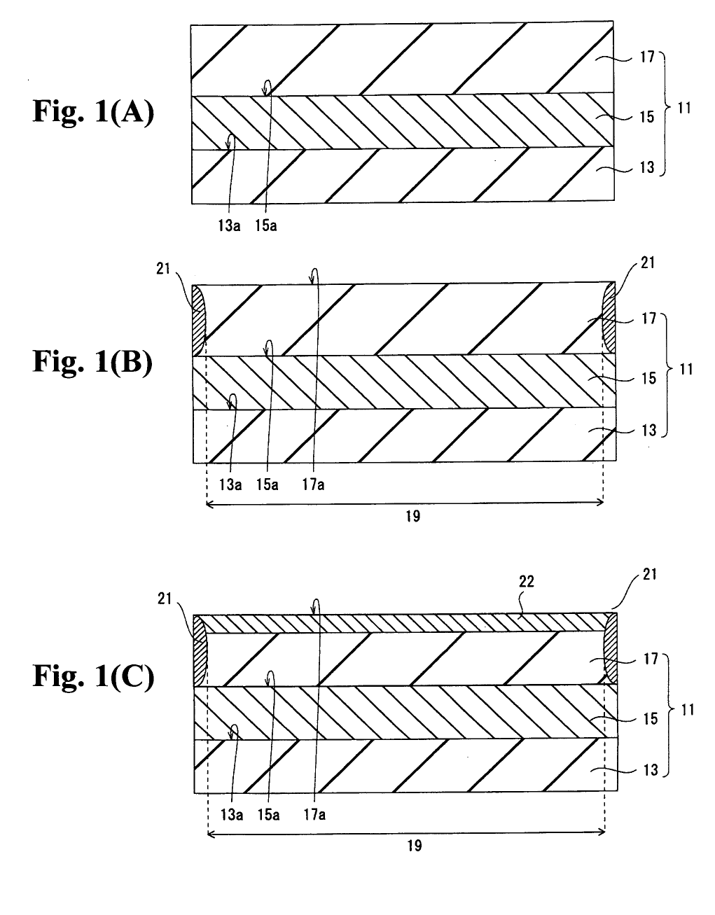

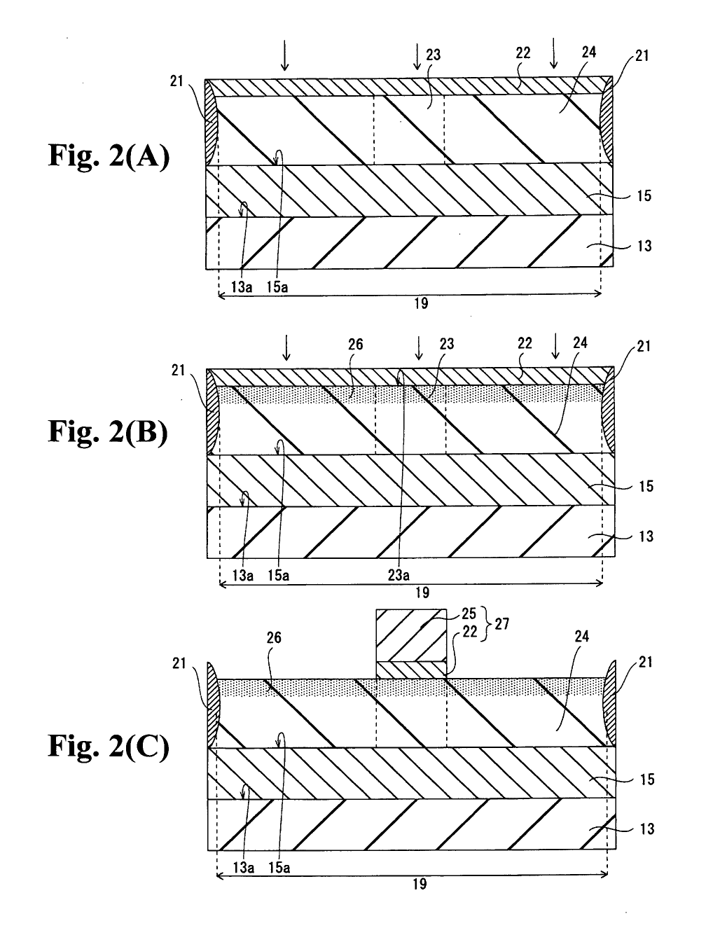

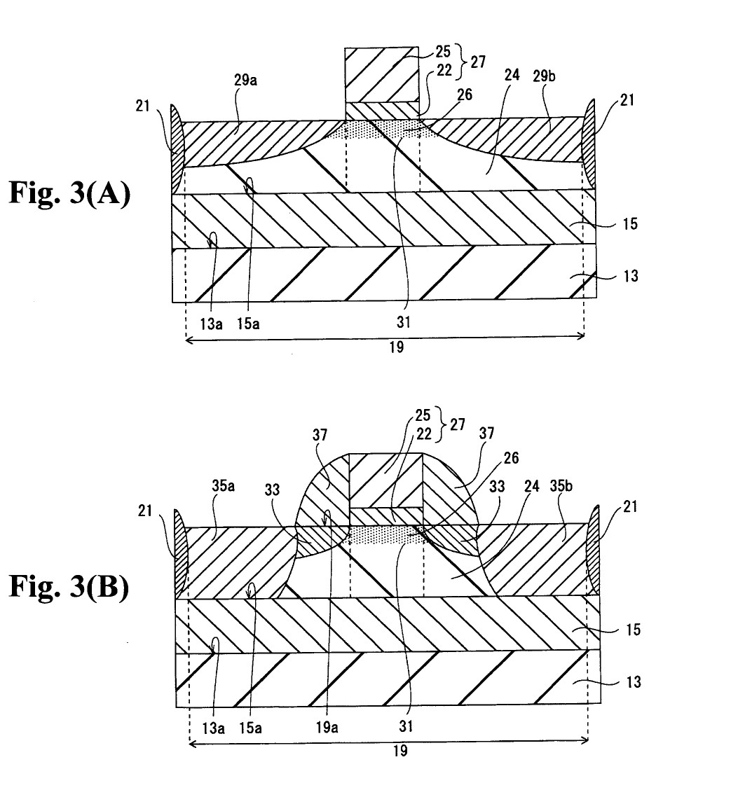

FIGS. 1(A) to 1(C) are schematic views No. 1 showing a process of producing a semiconductor device according to a first embodiment of the present invention. FIGS. 2(A) to 2(C) are schematic views No. 2 showing the process of producing the semiconductor device continued from FIG. 1(C) according to the first embodiment of the present invention. FIGS. 3(A) and 3(B) are schematic views No. 3 showing the process of producing the semiconductor device continued from FIG. 2(C) according to the first embodiment of the present invention. In FIGS. 1(A) to 1(C), FIGS. 2(A) to 2(C), and FIGS. 3(A) and 3(B), a sectional view of a structure obtained in each step is shown.

As shown in FIG. 1(A), first, an SOI substrate 11 is prepared. The SOI substrate 11 has a silicon (Si) support substrate 13; an insulation layer 15 formed on an upper surface 13a of the Si support substrate 13; and a silicon (Si) semiconductor layer 17 formed on an upper surface 15a of the insulation layer 15.

In the embodiment, the SOI substrate 11 may be prepared with a conventional method. That is, oxygen ions are introduced into a surface of a single-crystal silicon (Si) substrate, and then the Si substrate is annealed at a high temperature. In the high temperature annealing, the oxygen ions thus introduced couple with silicon constituting the substrate, thereby forming a silicon oxide layer functioning as an insulation layer.

With the process described above, it is possible to obtain the SOI substrate 11 having the three layers, i.e., the Si support substrate 13, the insulation layer 15 formed on the upper surface 13a of the Si support substrate 13, and the SOI semiconductor layer 17 formed on the upper surface 15a of the insulation layer 15. In the specification, the insulation layer 15 formed on the upper surface 13a of the Si support substrate 13 is also called as a BOX layer 15. Further, the SOI semiconductor layer 17 formed on the upper surface 15a of the BOX layer 15 in the SOI substrate 11 is also called as an SOI layer 17. In the embodiment, the SOI layer 17 of the SOI substrate 11 preferably has a thickness in a range between 30 nm and 60 nm.

In the next step, as shown in FIG. 1(B), element separation areas 21 are formed in the SOI layer 17 of the SOI substrate 11 for defining an element area 19, such that the element separation areas 21 have a depth reaching the BOX layer 15 from an upper surface 17a of the SOI layer 17. In the embodiment, the element separation areas 21 may be formed with a conventional method such as an LOCOS method, an STI method, and the like, so that the element separation areas 21 electrically separate the element area 19 on the SOI substrate 11. In particular, the element separation areas 21 are formed to have a depth reaching the BOX layer 15 from the upper surface 17a of the SOI layer 17, so that the element separation areas 21 electrically and securely separate the element area 19.

In the next step, a gate insulation film 22 is formed on the upper surface 17a of the SOI layer 17 to obtain a structure shown in FIG. 1(C). In the embodiment, the gate insulation film 22 may be formed with a conventional method such as thermal oxidation applied to the SOI layer 17. Through the thermal oxidation, the upper surface 17a of the SOI layer 17 is oxidized and becomes a silicon oxide film function as the gate insulation film 22.

As the next steps, the p-type impurity introduction step and the fluorine introduction step are performed. Note that the p-type impurity introduction step and the fluorine introduction step may be performed any order. In the embodiment, the p-type impurity introduction step is performed first followed by the fluorine introduction step.

In the p-type impurity introduction step, first, a p-type impurity corresponding to a conductive type of a channel area of the SOI layer 17 is introduced into a channel forming area 23 to obtain a structure shown in FIG. 2(A). In FIG. 2(A), the channel forming area 23 is represented as an area between two hidden lines. To this end, the p-type impurity is introduced into the element area 19 including the channel forming area 23.

In the embodiment, the channel forming area 23 is situated within the element area 19 corresponding to the channel area of the MOSFET, i.e., the n-type MOSFET, to be produced. A portion of the element area 19 where the p-type impurity is introduced becomes a p-type impurity introduced area 24. The p-type impurity preferably includes boron difluoride (BF₂), boron (B) and the likes. Further, the p-type impurity is introduced at a low concentration with a conventional ion introduction technology such as implantation, so that partial depletion does not occur. The low concentration at which partial depletion does not occur is appropriately adjusted according to a layer thickness of the SOI layer 17 and a layer thickness of the gate insulation film 22. An actual dosage of the p-type impurity is determined according to a design of the semiconductor device.

In the fluorine introduction step, fluorine is introduced into the channel forming area 23 to obtain a structure shown in FIG. 2(B). In the embodiment, fluorine is introduced into the element area 19 including the channel forming area 23 for increasing the threshold voltage of the n-type MOSFET to be produced.

More specifically, fluorine is introduced into the channel area of the n-type MOSFET to be produced, and the thermal processing step (described later) is performed. Accordingly, a level for trapping holes is generated at a boundary between the channel area and the gate insulation film 22. As a result, when the MOSFET is turned on, electrons moving in the channel area are trapped in an area surrounding the boundary, thereby increasing the threshold voltage.

As described above, fluorine is introduced at a concentration in a range between 5E13 cm⁻² and 5E14 cm⁻² with a conventional ion introduction technology such as implantation for increasing the threshold voltage of the n-type MOSFET. As a result, a portion of the element area 19 where fluorine is introduced becomes a fluorine introduced area 26. In the range between 5E13 cm⁻² and 5E14 cm⁻², it is possible to obtain the effect of increasing the threshold voltage of the n-type MOSFET to be produced, and the range may be adjusted as far as the same effect is obtained.

In the embodiment, fluorine is preferably introduced into the channel forming area 23 at a low acceleration voltage, that is, into the channel forming area 23 by a small depth from an upper surface 23a thereof. In the fluorine introduction step, when fluorine is introduced into the channel forming area 23 at a lower acceleration voltage, that is, fluorine is introduced into the channel forming area 23 by a small depth from the upper surface 23a thereof, the threshold voltage of the n-type MOSFET to be produced is found to increase from an experiment (described later). Accordingly, in the fluorine introduction step, fluorine is preferably introduced into the channel forming area 23 at a low acceleration voltage, i.e., about 5 KeV, so that the threshold voltage of the n-type MOSFET to be produced is increased.

After the p-type impurity introduction step and the fluorine introduction step, a gate electrode portion 27 including the gate insulation film 22 and a gate electrode 25 is formed to obtain a structure shown in FIG. 2(C). In the embodiment, the gate electrode portion 27 is formed with a conventional method. More specifically, a poly-silicon film is formed on the channel forming area 23 through the gate insulation film 22 with a CVD method and the likes, thereby forming the gate electrode 25. Then, the gate insulation film 22 and the gate electrode 25 are patterned through a conventional method such as a photolithography etching technology, a dry-etching technology, and the likes, thereby forming the gate electrode portion 27.

In the next step, an n-type impurity is introduced into the element area 19 with the gate electrode portion 27 as a mask to obtain a structure shown in FIG. 3(A). In the structure, a first main electrode area 29a, a second main electrode area 29b, and a channel area 31 between the first main electrode area 29a and the second main electrode area 29b are formed. The channel area 31 is situated in the channel forming area 23 below the gate electrode portion 27.

More specifically, the n-type impurity is introduced into the element area 19 with the gate electrode portion 27 as a mask with a conventional implantation technology. In the embodiment, the n-type impurity may include arsenic (As), phosphorus (P), and the likes. At this time, the gate electrode portion 27 is formed on the channel forming area 23 of the element area 19, and the channel forming area 23 becomes a non-introduced area where the n-type impurity is not introduced. Accordingly, the n-type impurity is not introduced into the channel forming area 23, and the channel forming area 23 remains as an area where the p-type impurity and fluorine are introduced. The channel forming area 23 thus remaining becomes the channel area 31. Portions of the element area 19 sandwiching the channel area 31, where the n-type impurity is introduced, become the first main electrode area 29a and the second main electrode area 29b functioning as a source area and a drain area, respectively.

Accordingly, in the embodiment, the n-type MOSFET is formed of the channel area 31 formed in the element area 19, where the p-type impurity and fluorine are introduced; the first main electrode area 29a and the second main electrode area 29b, where the n-type impurity is introduced; and the gate electrode portion 27 formed on the channel area 31.

In the embodiment, the n-type MOSFET may be provided with an LDD (Lightly Doped Drain) area 33 as shown in FIG. 3(B). When the the LDD area 33 is formed, first, the n-type impurity is introduced into the element area 19 by a small depth, not reaching the BOX layer 15, from the upper surface 19a thereof. At this time, the n-type impurity is introduced into an area at a concentration smaller than those of high concentration n-type impurity areas 35a and 35b. In the specification, the area is called as a low concentration n-type impurity area.

In the next step, sidewalls 37 are formed on the gate electrode portion 27 on both side surfaces thereof facing with each other in a gate longitudinal direction thereof. In the embodiment, the sidewalls 37 may be formed through depositing a silicon oxide film and the likes with a conventional CVD method.

In the next step, using the gate electrode portion 27 and the sidewalls 37 as a mask, the n-type impurity is introduced one more time into the element area 19 by a depth deeper than the low concentration n-type impurity area at a high concentration.

At this time, the n-type impurity is not introduced into a portion below the gate electrode portion 27 and the sidewalls 37, so that the low concentration n-type impurity area remains. The low concentration n-type impurity area thus remaining becomes the LDD area 33. Further, when the n-type impurity is introduced one more time into the element area 19, the high concentration n-type impurity areas 35a and 35b are formed outside the sidewalls 37, and function as the source area and the drain area, respectively.

After the n-type MOSFET is produced as described above, an annealing process, or a thermal processing step is performed. In the thermal processing step, the p-type impurity, fluorine, and the n-type impurity thus introduced are activated through a heating process. To this end, the thermal processing is performed at a temperature of 1,000° C. with a conventional technology such as RTA (Rapid Temperature Annealing) and the likes. In the embodiment, an annealing temperature is set at 1,000° C., and is not limited thereto. The annealing temperature may be adjustable as far as the same effect is obtained.

In the thermal processing step, fluorine introduced in the fluorine introduction step is activated. Accordingly, the potential at the boundary between the channel area 31 and the gate insulation film 22 increases. As a result, it is possible to increase the threshold voltage of the MOSFET thus produced.

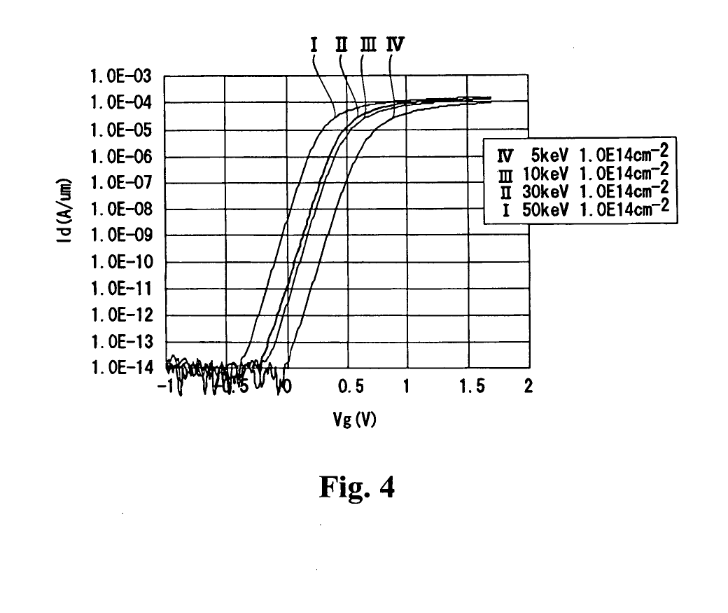

An experiment was conducted for evaluating a property of the MODFET produced with the method described above. FIG. 4 is a graph showing a relationship between a drain current and a gate voltage of the semiconductor device for evaluating the threshold voltage of the n-type SOI-MOSFET according to the first embodiment of the present invention. In FIG. 4, the vertical axis represents the drain current (Id) with a unit of A/μm, and the horizontal axis represents the gate voltage (Vg) with a unit of V.

In FIG. 4, a curve I represents an Id-Vg property of the MOSFET in which fluorine was introduced at an acceleration voltage of 50 keV in the fluorine introduction step described above. A curve II represents an Id-Vg property of the MOSFET in which fluorine was introduced at an acceleration voltage of 30 keV in the fluorine introduction step described above. A curve III represents an Id-Vg property of the MOSFET in which fluorine was introduced at an acceleration voltage of 10 keV in the fluorine introduction step described above. A curve VI represents an Id-Vg property of the MOSFET in which fluorine was introduced at an acceleration voltage of 5 keV in the fluorine introduction step described above.

In the experiment, the MOSFET had the SOI layer 17 having a thickness of 40 nm and the gate electrode 25 having a thickness of 2.5 nm. In the p-type impurity introduction step, BF₂ was introduced at a concentration of 2.7E12 cm⁻². In the fluorine introduction step, fluorine was introduced at a concentration of 1.0E14 cm⁻².

As shown in FIG. 4, when fluorine was introduced at a lower acceleration voltage, the gate voltage of the MOSFET shifts toward a positive side, indicating that the threshold voltage increases. From the result, it is found that when fluorine is introduced at a lower acceleration voltage into the channel forming area 23 by a small depth from the upper surface 23a thereof in the fluorine introduction step, it is possible to increase the threshold voltage. Accordingly, when the n-type MOSFET is produced with the method of producing the semiconductor according to the first embodiment, it is possible to obtain the n-type MOSFET with the threshold voltage at an adjusted high level.

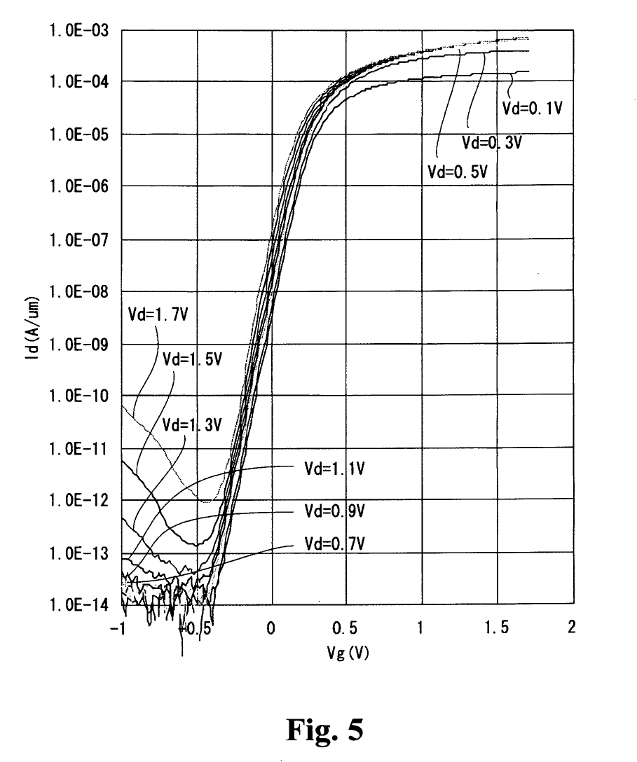

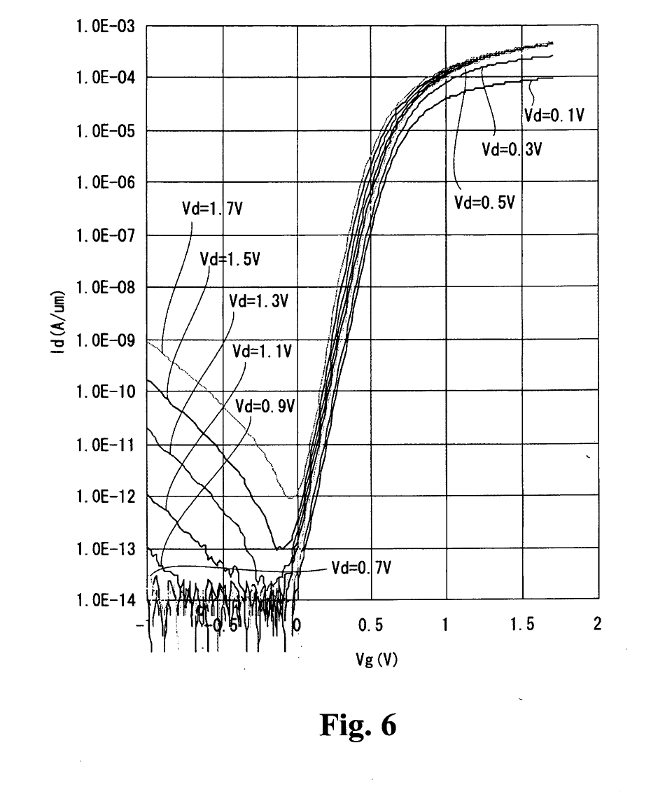

FIG. 5 is a graph showing a relationship between the drain current and the gate voltage of the semiconductor device for evaluating single latchup property of the n-type SOI-MOSFET according to the first embodiment of the present invention. FIG. 6 is a graph showing a relationship between the drain current and the gate voltage of the semiconductor device for evaluating the single latchup property of the n-type SOI-MOSFET according to the first embodiment of the present invention. In FIGS. 5 and 6, the vertical axis represents the drain current (Id) with a unit of A/μm, and the horizontal axis represents the gate voltage (Vg) with a unit of V.

In FIG. 5, curves represent Id-Vg properties of the MOSFET, in which fluorine was introduced at an acceleration voltage of 50 keV in the fluorine introduction step described above, and a drain voltage (Vd) was changed between 0.1 to 1.7 V with an interval of 0.2 V. In FIG. 6, curves represent Id-Vg properties of the MOSFET, in which fluorine was introduced at an acceleration voltage of 5 keV in the fluorine introduction step described above, and the drain voltage (Vd) was changed between 0.1 to 1.7 V with an interval of 0.2 V.

In the experiment, the MOSFET had the SOI layer 17 having a thickness of 40 nm and the gate electrode 25 having a thickness of 2.5 nm. In the p-type impurity introduction step, BF₂ was introduced at a concentration of 2.7E12 cm⁻². In the fluorine introduction step, fluorine was introduced at a concentration of 1.0E14 cm⁻².

As shown in FIGS. 5 and 6, the gate voltage does not show a significant difference among the curves. That is, in FIGS. 5 and 6, the Id-Vg properties do not exhibit a drastic sub-threshold property, indicating that a parasite bipolar transistor does not operate. Accordingly, a single latchup did not occur in the MOSFET used in the experiment (refer to the description in BACKGROUND OF THE INVENTION AND RELATED ART STATEMENT).

As described above, when the n-type MOSFET is produced with the method of producing the semiconductor according to the first embodiment, fluorine is introduced at a low acceleration voltage without increasing a dosage of the p-type impurity. Accordingly, it is possible to increase the threshold voltage without inducing the single latchup.

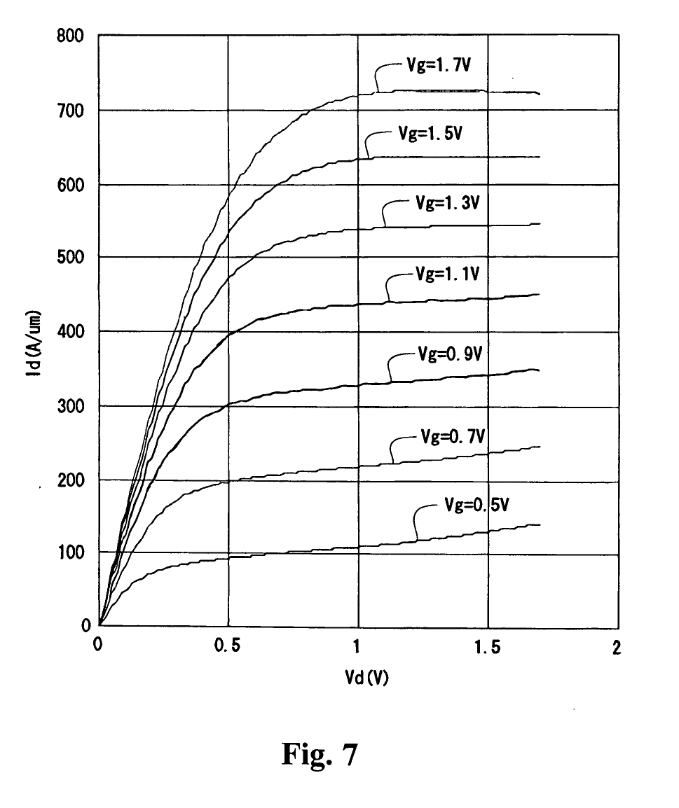

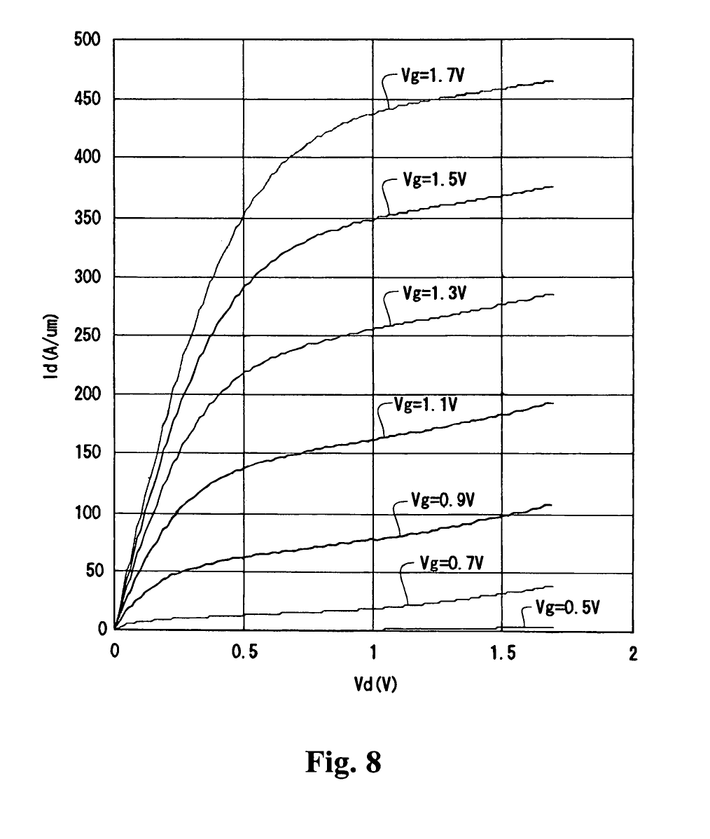

FIG. 7 is a graph showing a relationship between the drain current and the drain voltage of the semiconductor device for evaluating kink property of the n-type SOI-MOSFET according to the first embodiment of the present invention. FIG. 8 is a graph showing a relationship between the drain current and the drain voltage of the semiconductor device for evaluating the kink property of the n-type SOI-MOSFET according to the first embodiment of the present invention. In FIGS. 7 and 8, the vertical axis represents the drain current (Id) with a unit of A/μm, and the horizontal axis represents the drain voltage (Vd) with a unit of V.

In FIG. 7, curves represent Id-Vd properties of the MOSFET, in which fluorine was introduced at an acceleration voltage of 50 keV in the fluorine introduction step described above, and the gate voltage (Vg) was changed between 0.5 to 1.7 V with an interval of 0.2 V. In FIG. 8, curves represent Id-Vd properties of the MOSFET, in which fluorine was introduced at an acceleration voltage of 5 keV in the fluorine introduction step described above, and the gate voltage (Vg) was changed between 0.5 to 1.7 V with an interval of 0.2 V.

As shown in FIGS. 7 and 8, the drain current does not show a significant difference among the curves. That is, it is indicated that a decrease in the threshold voltage due to accumulation of positive holes does not occur. Accordingly, a kink did not occur in the MOSFET used in the experiment (refer to the description in BACKGROUND OF THE INVENTION AND RELATED ART STATEMENT).

As described above, when the n-type MOSFET is produced with the method of producing the semiconductor according to the first embodiment, fluorine is introduced at a low acceleration voltage without increasing a dosage of the p-type impurity. Accordingly, it is possible to increase the threshold voltage without inducing the kink.

As described above, in the embodiment, fluorine and the p-type impurity determining the conductive type of the channel area 31 are introduced into the channel forming area 23, i.e., the channel area of the MOSFET to be produced. Accordingly, it is possible to increase the threshold voltage of the MOSFET to be produced. Further, it is not necessary to increase the concentration of the p-type impurity in the channel area 31, so that partial depletion does not occur in the MOSFET thus produced. Accordingly, it is possible to increase the threshold voltage of the MOSFET without inducing the single latchup or the kink.

In the embodiment, when the MOSFET is produced using the SOI substrate 11, the step of introducing fluorine into the channel forming area 23 at a low acceleration voltage is just added to a conventional production flow. Accordingly, it is possible to prevent production put-through from lowering upon adjusting the threshold voltage.

The disclosure of Japanese Patent Application No. 2007-036721, filed on Feb. 16, 2007, is incorporated in the application.

While the invention has been explained with reference to the specific embodiments of the invention, the explanation is illustrative and the invention is limited only by the appended claims.

What is claimed is:

1. A method of producing a semiconductor device, comprising the steps of:
introducing a p-type impurity corresponding to a conductive type of a channel area into a channel forming area;
introducing fluorine into the channel forming area at a low acceleration voltage; and
thermally processing a substrate to increase a threshold voltage.

2. The method of producing a semiconductor device according to claim 1, where, in the step of introducing the p-type impurity, the p-type impurity is introduced at a concentration so that partial depletion does not occur.

3. The method of producing a semiconductor device according to claim 1, where, in the step of introducing fluorine, fluorine is introduced at a concentration in a range between 5E13 cm⁻² and 5E14 cm⁻².
